(19) United States
(12) Patent Application Publication
(10) Pub. No.: US 2018/0274092 A1
(43) Pub. Date: Sep. 27, 2018

(54) SEMICONDUCTOR MANUFACTURING APPARATUS AND METHOD OF MANUFACTURING SEMICONDUCTOR DEVICE

(71) Applicant: TOSHIBA MEMORY CORPORATION, Tokyo (JP)

(72) Inventors: Masayuki KITAMURA, Yokkaichi Mie (JP); Atsuko SAKATA, Yokkaichi Mie (JP); Satoshi WAKATSUKI, Yokkaichi Mie (JP)

(73) Assignee: TOSHIBA MEMORY CORPORATION, Tokyo (JP)

(21) Appl. No.: 15/695,929

(22) Filed: Sep. 5, 2017

(30) Foreign Application Priority Data
Mar. 23, 2017 (JP) 2017-057717

(51) Int. Cl. C23C 16/44; H01L 21/285; C23C 16/455; C23C 16/458; H01L 21/205; C30B 29/06

(52) U.S. Cl. CPC C23C 16/4401; C23C 16/4412; H01L 21/28556; C23C 16/45565; C23C 16/4587; H01L 21/205; C30B 29/06; C23C 16/45527

(57) ABSTRACT

A semiconductor manufacturing apparatus includes a reaction chamber configured to perform a process on a semiconductor substrate using a gas mixture comprising a first gas, and a first path configured to exhaust resultant gas that comprises the first gas from the reaction chamber. The semiconductor manufacturing apparatus further includes a first trap provided in the first path and configured to extract at least a portion of the first gas from the resultant gas, and a second path in which the trap is not provided and configured to exhaust the resultant gas from the reaction chamber.

### CROSS-REFERENCE TO RELATED APPLICATION

This application claims the benefit of and priority to Japanese Patent Application No. 2017-057717, filed Mar. 23, 2017, the entire contents of which are incorporated herein by reference.

### FIELD

Embodiments described herein relate generally to a semiconductor manufacturing apparatus and a method of manufacturing a semiconductor device.

### BACKGROUND

In some three-dimensional semiconductor devices, a surface area of a structure formed on a semiconductor substrate during a manufacturing process can be large. In some implementations, when a film is formed by chemical vapor deposition (CVD) on the structure, more reaction gas can be used to form the film when the surface area is large, as compared to implementations in which the surface area is small. This can lead to an increase in manufacturing costs of the semiconductor device.

### DESCRIPTION OF THE DRAWINGS

FIG. 1 is a diagram schematically illustrating a configuration of some embodiments of a semiconductor manufacturing apparatus according to a first aspect.

FIG. 2A, FIG. 2B, FIG. 2C, and FIG. 2D are longitudinal cross-sectional views illustrating examples of a sequence of process steps of some embodiments of a method of manufacturing a semiconductor device according to the first aspect.

FIG. 3 is a flowchart illustrating a high-level description of the process steps of the embodiments of the method of manufacturing the semiconductor device according to the first aspect.

FIG. 4 is a diagram schematically illustrating a configuration of modified embodiments of the semiconductor manufacturing apparatus according to the first aspect.

FIG. 5 is a diagram schematically illustrating a configuration of modified embodiments of the semiconductor manufacturing apparatus according to the first aspect.

FIG. 6 is a diagram schematically illustrating a configuration of modified embodiments of the semiconductor manufacturing apparatus according to the first aspect.

FIG. 7 is a diagram schematically illustrating a configuration of some embodiments of a semiconductor manufacturing apparatus according to a second aspect.

FIG. 8A and FIG. 8B are diagrams schematically illustrating a configuration of modified embodiments of the semiconductor manufacturing apparatus according to the second aspect.

FIG. 9A and FIG. 9B are diagrams schematically illustrating a configuration of modified embodiments of the semiconductor manufacturing apparatus according to the second aspect.

FIG. 10 is a diagram schematically illustrating a configuration of modified embodiments of the semiconductor manufacturing apparatus according to the second aspect.

FIG. 11 is a diagram schematically illustrating some embodiments of a semiconductor manufacturing apparatus that includes two semiconductor manufacturing apparatuses, according to a third aspect.

### DETAILED DESCRIPTION

Some example embodiments provide for a semiconductor manufacturing apparatus that can use a reduced amount of reaction gas in a manufacturing process and can provide for reduced costs for manufacturing a semiconductor device.

In some embodiments, according to one aspect, a semiconductor manufacturing apparatus includes a reaction chamber configured to perform a process on a semiconductor substrate using a gas mixture including a first gas, and a first path configured to exhaust resultant gas that includes the first gas from the reaction chamber. The semiconductor manufacturing apparatus further includes a first trap provided in the first path configured to extract at least a portion of the first gas from the resultant gas, and a second path in which the trap is not provided and is configured to exhaust the resultant gas from the reaction chamber.

In some embodiments, according to another aspect, a semiconductor manufacturing apparatus includes a first reaction chamber configured to perform a process on a first semiconductor substrate using a gas mixture, and a first path configured to recover resultant gas from the process. The semiconductor manufacturing apparatus further includes a second reaction chamber connected to the first path and configured to perform a process on a second semiconductor substrate using the resultant gas.

In some embodiments, according to another aspect, a method of manufacturing a semiconductor device includes forming a first film on a semiconductor substrate using a first gas mixture and discharging the first gas mixture after forming the first film. The method further includes forming a second film on the first film using a second gas mixture different from the first gas mixture and including a third gas, extracting the third gas from the second gas mixture after forming the second film to generate resultant gas that does not include the third gas, and discharging the resultant gas.

Embodiments are described herein with reference to the accompanying drawings. The drawings are schematic and are not necessarily consistent with actual relations between thicknesses and planar dimensions as well as ratios of thicknesses between different layers of embodiments described herein. Other features may also be depicted to scale. A same feature may be illustrated as having different dimensions or ratios in different figures. Further, directional terms such as up, down, left, and right are used in a relative context with an assumption that a surface, on which circuitry may be formed, of the below-described semiconductor substrates faces up, and thus these directional terms do not necessarily correspond to directions that correspond to a direction of gravitational acceleration. In the present disclosure and in each of the drawings, same reference numerals may be given to elements having the same or similar functions and configurations, and detailed description thereof will be omitted as appropriate.

In the following description, an XYZ orthogonal coordinate system is used for convenience of explanation. In this coordinate system, two directions parallel to the surface of a semiconductor substrate and orthogonal to each other are referred to as an X direction and a Y direction, respectively. A direction orthogonal to both the X direction and the Y direction is referred to as a Z direction.

### (First Aspect)

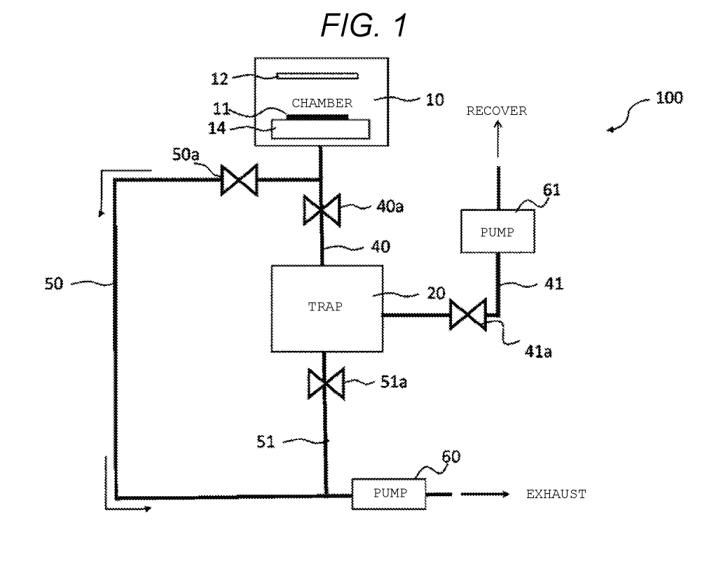

FIG. 1 is an example of a diagram schematically illustrating a configuration of some embodiments of a semiconductor manufacturing apparatus 100 according to a first aspect. The semiconductor manufacturing apparatus 100 includes a chamber (e.g. a reaction chamber) 10, a trap 20, valves 40a, 41a, 50a, and 51a, recovery lines (e.g. channels) 40 and 41, and exhaust lines (e.g. channels) 50 and 51.

The chamber 10 can serve as a reaction chamber in which a film-formation process is performed on a surface of a semiconductor substrate 11 by CVD. However, in some embodiments the film-formation process may be performed by methods other than the CVD. In the chamber 10, for example, a shower head 12 and a stage 14 are provided. The semiconductor substrate 11 can be mounted on the stage 14, which can be configured to control a temperature of the semiconductor substrate 11 (e.g. can include a heating and/or cooling device). The chamber 10 is provided with an exhaust tube (not illustrated) and is connected to (e.g. is in gaseous and/or liquid communication with) at least two paths: a first path that includes a recovery line 40 and at least one of a recovery line 41 and an exhaust line 51, and a second path that includes an exhaust line 50, which are described below.

The shower head 12 is connected to a gas supply tube (not illustrated), and a supplied reaction gas (which may be, for example, a gas mixture that includes two or more gases), whose flow rate can be adjusted (e.g. by a flow rate valve), is supplied into the chamber 10 from the shower head 12 through the gas supply tube. A film is formed on the surface of the semiconductor substrate 11 by the supplied reaction gas. A “resultant gas,” which can include unreacted reaction gas (e.g. an excess of the reaction gas that was not consumed in the film formation process) and/or a newly generated product gas, is discharged out of the chamber 10 through the exhaust tube.

The trap 20 is configured to extract a first gas (e.g. a desired gas or gas of interest, such as unreacted reaction gas) from the resultant gas. The trap 20 includes a control mechanism including a heating mechanism and/or a cooling mechanism. The trap 20 is connected to the exhaust tube of the chamber 10 via the recovery line 40. The resultant gas can collect in the trap 20 through the recovery line 40.

The trap 20 is also connected to the recovery line 41, and the first gas extracted by the trap 20 can be collected in, for example, a tank (not illustrated) through the recovery line 41. The recovery lines 40 and 41 may be channels that provide for gaseous and/or liquid communication.

The trap 20 is also connected to the exhaust line 51, and an undesired gas (e.g. a product gas of the resultant gas) in the trap 20 can be exhausted to the outside of the semiconductor manufacturing apparatus 100 through the exhaust line 51.

In the depicted embodiments, the resultant gas in the chamber 10 can be selectively exhausted through the second path including the exhaust line 50 connected to the chamber 10 without being recovered by the trap 20, or can be exhausted through the first path including the recovery line 40, the recover line 41, and the exhaust line 51.

Valves 40a, 41a, 50a, and 51a are provided in the recovery lines 40 and 41 and the exhaust lines 50 and 51, respectively. When the valve is opened, the gas can flow. On the other hand, when the valve is closed, the gas is blocked. The valve may be referred to as “closed” or in a “closed” state when, for example, flow of gas through the valve is no greater than about 10%, no greater than about 5%, or no greater than about 1% of a maximum flow. The valve may be referred to as “open” or in an “open” state when, for example, flow of gas through the valve is at least about 90%, at least about 95%, or at least about 99% of a maximum flow.

Pumps 60 and 61 are provided at terminals of the recovery line and the exhaust line, respectively, and a pressure difference can be generated by the pumps 60 and 61 to direct gas flow. In some embodiments, either or both pumps 60 and 61 may be omitted. For example, the gas can also be moved by a pressure difference generated by heating of the trap 20.

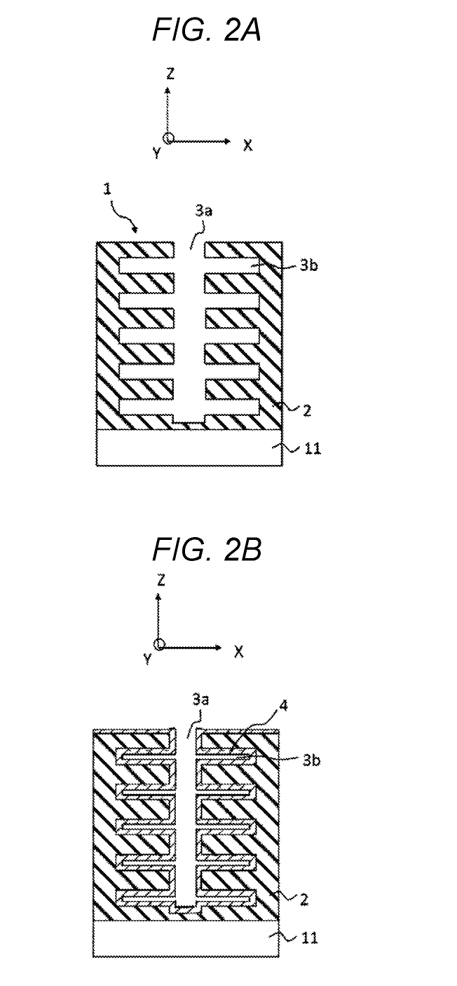

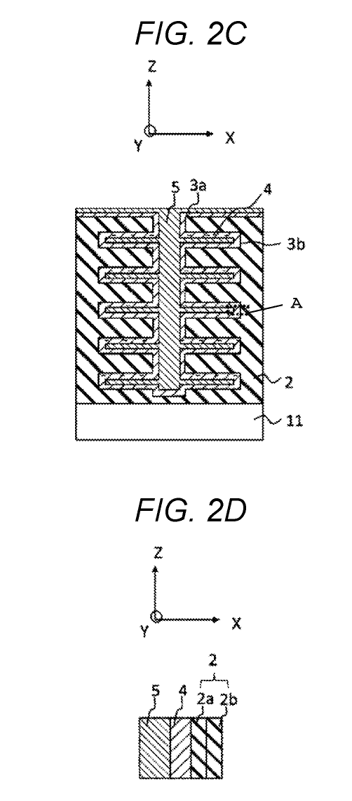

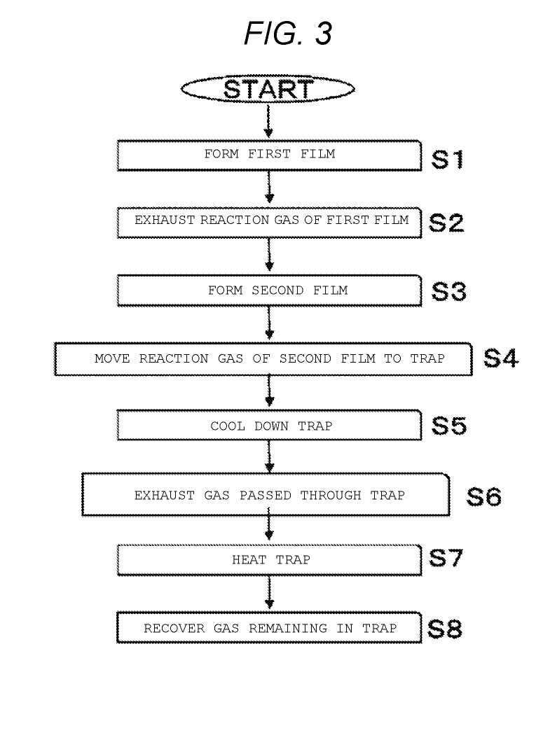

Next, a description will be given of a method of manufacturing a semiconductor device using the semiconductor manufacturing apparatus 100 according to some embodiments, with reference to FIG. 2A through FIG. 2D, and FIG. 3. FIG. 2A through FIG. 2C are longitudinal cross-sectional views illustrating examples of a sequence of process steps for explaining the method of manufacturing the semiconductor device.

As illustrated in FIG. 2A, a semiconductor device 1 is provided. The semiconductor device 1 includes a film 2 disposed on a semiconductor substrate 11. For example, the semiconductor substrate 11 may include a silicon substrate. The film 2 may include an insulating film or a conductive film, for example. Furthermore, the film 2 may also be a stacked film that includes a plurality of films. An example of the film 2 is a silicon oxide film. Another film may also be formed adjacent to the film 2 in the depicted X direction.

A groove 3a and a plurality of grooves 3b are defined by the film 2. The groove 3a extends in the longitudinal direction (the depicted Z direction), and the grooves 3b extend in the left and right direction, that is, the transverse direction (the X direction) around the groove 3a. In this configuration of the groove 3a extending in the Z direction and the grooves 3b extending in the left and right direction (the X direction) around the groove 3a, the grooves 3a and 3b may be described as “fishbone shaped”, for example, as illustrated in FIG. 2A through FIG. 2D. The grooves 3a and 3b extend in the depicted Y direction (a front and rear direction in the drawings), and may, in some embodiments, extend longer in the Y direction than in either of the Z direction or the X direction. The grooves 3a and 3b provide for a large surface area of the semiconductor device 1. A surface area of the semiconductor device 1 is at least equal to a sum of the surface areas of surfaces of the grooves 3a and 3b.

The fishbone shape configuration of the grooves 3a and 3b is illustrated as an example of the semiconductor device 1 having a large surface area, but the semiconductor device 1 can have any other appropriate shape. For example, the semiconductor device 1 may define a plurality of grooves that extend in the longitudinal direction.

Next, a first film 4 is formed on the film 2 (and may be deposited on one or more surfaces of the grooves 3a and 3b), by CVD, for example. The CVD may be performed in a chamber 10 of a semiconductor manufacturing apparatus 100. The first film 4 may include an insulating film and/or a conductive film. An example that implements a conductive film as the first film 4 is illustrated, and a tungsten (W) film including silicon (Si) or boron (B) as an additive is illustrated as an example of the conductive film. The film formation using CVD is carried out. When the first film 4 is formed on the semiconductor substrate 11 illustrated in FIG. 2A, the first film 4 can be formed (e.g. conformally formed) on surfaces of the grooves 3a and 3b and the surface of the film 2 as illustrated in FIG. 2B.

Next, a second film 5 is also formed using CVD, for example. An example that implements a conductive film as the second film 5 is illustrated, and a tungsten film is illustrated as an example of the conductive film. As illustrated in FIG. 2C, the second film 5 is deposited in the grooves 3a and 3b (e.g. the grooves are filled with the second film 5), and the second film 5 is formed on the surface of the film 2. In the depicted embodiments, the first film 4 and the second film 5 are formed in the same chamber 10 of the semiconductor manufacturing apparatus 100.

In order to more clearly show a structure of the resultant film, FIG. 2D illustrates a schematic diagram obtained by enlarging a section “A” indicated by a broken line in FIG. 2C. FIG. 2D illustrates a selected portion of each film. As illustrated in FIG. 2D, the semiconductor device 1 of the depicted embodiments includes the film 2 which includes two layers of film. In other embodiments, the film 2 may include only one layer, or may include more than 2 layers. The film 2 includes, for example, a barrier metal film (e.g. a titanium nitride (TiN) film) 2a in contact with the first film 4 and a block film (e.g. an aluminum oxide (Al₂O₃) film) 2b in contact with the barrier metal film 2a.

FIG. 3 is a flowchart showing example process steps of the method of manufacturing the semiconductor device described above with reference to FIG. 2A through FIG. 2D.

First, the semiconductor device 1 is provided on the stage 14 in the chamber 10 of the semiconductor manufacturing apparatus 100. The valve 40a is in or is set to a “closed” state, and the valve 50a is in or is set to an “open” state. A reaction gas is supplied into the chamber 10 from the shower head 12 so as to form the first film 4 in the grooves 3a and 3b. The first film 4, which can be, for example, a tungsten film (for example, a tungsten silicide film) is formed by CVD and includes Si or B. In some implementations of forming the first film 4, tungsten hexafluoride (WF₆) can be used as a material gas, silane (SiH₄) can be used as a reducing gas, and nitrogen (N₂) or argon (Ar) can be used as a carrier gas. The reaction represented by the following chemical formula (1) occurs in the chamber 10.

2WF₆(g)+2SiH₄(g)→W(s)+3SiF₄(g)+6H₂ (1)

Through the process described by chemical formula (1), the first film 4 is formed on the semiconductor substrate 11 (e.g. on the surface of the film 2 including the surfaces of the grooves 3a and 3b) (S1).

During this process, the valve 40a remains in the “closed” state, and the valve 50a remains in the “open” state. Thus, resultant gas that includes unreacted reaction gas and/or product gas is discharged through the exhaust line 50 (S2).

Next, the valve 50a is set to a “closed” state, the valves 40a and 51a are set to an “open” state, and the second film 5 is formed. The second film 5 is, for example, a tungsten film formed by CVD. In some implementations of forming the second film 5, W₆ is used as a material gas, hydrogen (H₂) is used as a reducing gas, and N₂ or Ar is used as a carrier gas. The reaction represented by the following chemical formula (2) occurs in the chamber 10.

WF₆(g)+3H₂ (g)→W (s)+6HF (g) (2)

Though the process described by chemical formula (2), the second film 5 is formed on the first film 4 (S3). This process may be performed, for example, at a temperature of about 400 degrees Celsius (° C.) or higher, such as at about 420° C. or higher, at about 440° C. or higher, at about 460° C. or higher, at about 480° C. or higher, or at about 500° C. or higher. Since the valve 40a is in the “open” state, resultant gas including the unreacted reaction gas and/or newly generated product gas moves to the trap 20 through the recovery line 40 (S4).

The interior of the trap 20 is set to, for example, a temperature about equal to, or lower than, a melting point and a boiling point of a gas of the resultant gas that is to be collected and/or recovered. For example, if the WF₆ gas, which has a melting point of about 2° C. and a boiling point of about 18° C., is to be recovered, the interior of the trap 20 is set to about 2° C. or lower (e.g. is set to about 1.0° C. or lower, to about 0° C. or lower, or to about −1.0° C. or lower) via a cooling mechanism of the trap 20 (S5). The WF₆ gas being in a gaseous state in the chamber 10 and in the recovery line 40 is condensed and solidified in the trap 20 into a solid state, and is thus accumulated in the trap 20. However, since other gases of the resultant gas can have a melting point lower than the melting point of the WF₆ gas, those other gases remain in a gaseous state even when the WF₆ gas is in the solid state.

In some implementations, of the gases moving to the trap 20, the WF₆ gas selectively becomes a solid and is accumulated in the trap 20, and the other gases pass through the trap 20 and are exhausted through the exhaust line 51 (S6). In other implementations, gases other than the WF₆ gas may also become a solid in the trap 20.

Next, the valves 40a and 51a are set to a “closed” state, and the valve 41a is set to an “open” state. The trap 20 is heated by a heating mechanism such that the interior of the trap 20 is set to, for example, a temperature that is about equal to or higher than the boiling point of the WF₆ gas (such as, for example, about 18° C. or higher, about 20° C. or higher, about 22° C. or higher, or about 24° C. or higher), and thus the solid WF₆ returns to a gaseous state (S7). The gaseous WF₆ is recovered in, for example, a tank through the recovery line 41 (S8).

The above-described exhaust and recovery can be implemented by a process that involves using a pressure difference, such as a pressure difference generated by the pumps 60 and 61 provided at the terminals of the lines and/or a pressure difference due to a vapor pressure when the trap 20 is heated. Although not illustrated in the drawings, a device including, for example, a central processing unit (CPU) and/or computer readable instructions stored in a memory that can be accessed and/or executed by the CPU may be provided inside or outside the apparatus, and may be configured to control the supply, recovery, and/or exhausting of gases involved in the above-described processes.

In the manner described above, manufacture of the semiconductor device 1 can be performed using the semiconductor manufacturing apparatus 100 of some embodiments.

According to some embodiments of the semiconductor manufacturing apparatus 100 described herein, the semiconductor manufacturing apparatus 100 includes the trap 20 provided with the heating mechanism and the cooling mechanism, and thus it is possible to selectively recover a desired gas. The semiconductor manufacturing apparatus 100 can be configured based on a melting point and/or a boiling point of the desired gas.

For example, when multiple films are formed sequentially (e.g. in a repeated and/or continuous process), some resultant gas used for the formation of a first film can react with the desired gas used for the formation of the second film, and thus there is a possibility of lowering a recovery rate of the desired gas in the trap 20. The semiconductor manufacturing apparatus 100 can reduce or eliminate this risk by implementing a separate path that includes the exhaust line 50 which connects to a gas flow path from the chamber 10 to a recovery section or to an exhaust section at a location upstream of the trap 20. In some comparative embodiments, for example, when there is no exhaust line 50 provided upstream of the trap 20, SiH₄ used for the formation of the first film 4 remains in the trap 20 and reacts with WF₆ to form an undesired solid (for example, WSiₓ), and the amount of reusable WF₆ gas may be reduced.

According to some embodiments of the semiconductor manufacturing apparatus described herein, an exhaust line can branch upstream of the trap, and this can be used to increase a recovery rate of the desired gas.

It should be noted that the trap described in the depicted embodiments is discussed by way of example and any other appropriate mechanism may be used to recover the desired gas. Further, the reaction gas described in the depicted embodiments is merely an example, and any other type of gas may be used in the formation of the first film and the second film.

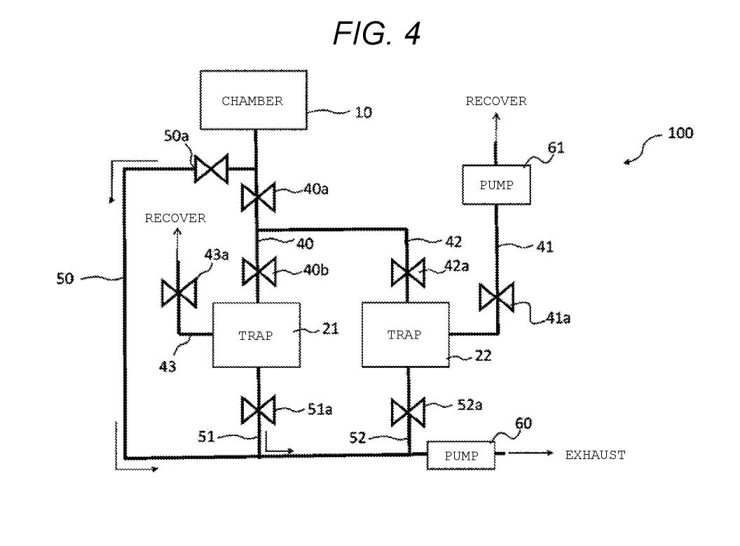

Modified examples of the semiconductor manufacturing apparatus 100 according to the first aspect will be described below with reference to FIG. 4 through FIG. 6.

As illustrated in FIG. 4, in some embodiments, the semiconductor manufacturing apparatus 100 can include two or more traps, including a first trap 21 and a second trap 22. When two traps are provided, a desired gas can be recovered by each or either of the first trap 21 and the second trap 22. Accordingly, during heating treatment for recovering the desired gas by the first trap 21, the film-formation process can be performed in the chamber 10 connected to the second trap 22, and recovery or operational efficiency can be improved.

In the embodiments shown in FIG. 4, the semiconductor manufacturing apparatus 100 includes three paths: a first path including a recovery line 40 and provided with a valve 40b and a trap 21, a second path including an exhaust line 50, and a third path including a recovery line 42 and provided with a valve 42a and a trap 22. When a desired gas (e.g. unreacted reaction gas) is collected in the first trap 21 from the chamber 10, the valves 50a and 42a are set to a “closed” state. When the first trap 21 is being used, for example, for heating collected gas, and is not being used to collect new gas or is not available for such collection, the valves 40a and 42a are set to an “open” state and the valves 50a and 40b are set to a “closed” state, and thus the new reaction gas emerging from the chamber 10 can be collected in the second trap 22.

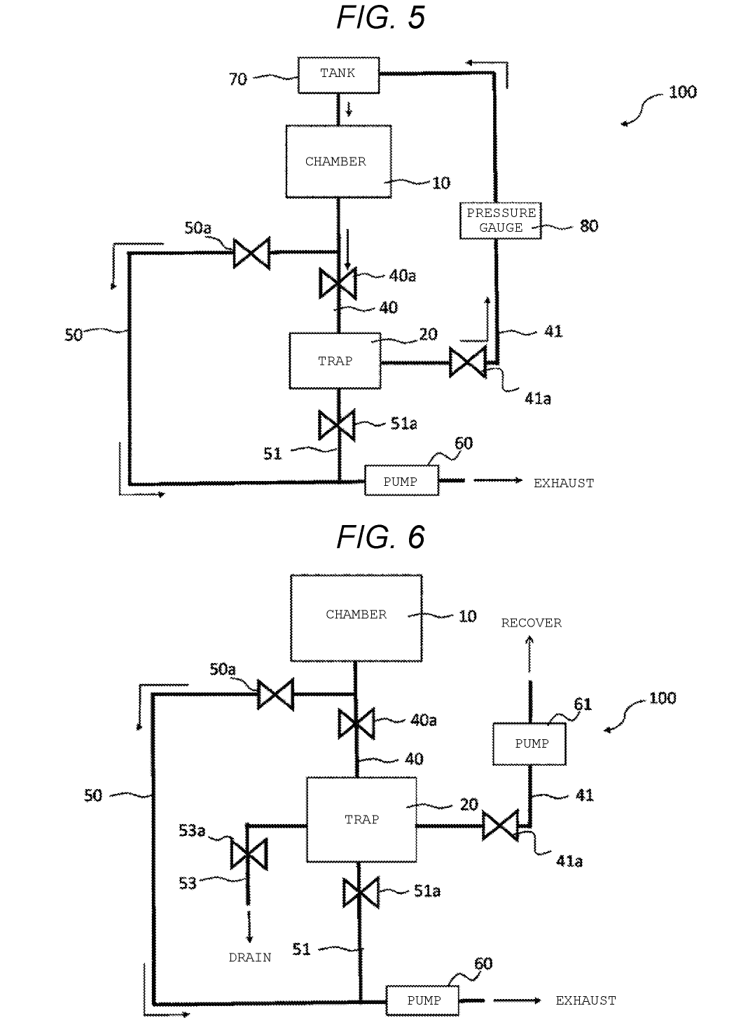

As illustrated in FIG. 5, in some embodiments of the semiconductor manufacturing apparatus 100, a desired gas recovered from the trap 20 may be returned to the chamber 10 after being temporarily recovered in a tank 70. For example, the tank 70 is connected to a gas supply tube for supplying a gas into the chamber 10. At this time, a pressure in the tank 70 is set to be low so that the desired gas recovered from the trap 20 moves to the tank 70 through the recovery line 41 and is again supplied to the chamber 10. For example, the pressure of the tank 70 may be lower than a pressure indicated by a pressure gauge 80 provided on the recovery line 41.

As illustrated in FIG. 6, in some embodiments, the semiconductor manufacturing apparatus 100 can include a drain line 53 separate from the exhaust line to drain an undesired liquid generated in the trap 20.

Processes performed by or for the example apparatuses described above (e.g. controlling pressure and/or draining of a trap) can be performed by a CPU and/or computer readable instructions stored in a memory that can be accessed and/or executed by the CPU, which may be provided inside or outside the apparatuses, for example.

In the above-described embodiments, the tungsten silicide film and the tungsten film are provided as examples of the first film 4 and the second film 5, but other films may be implemented additionally or alternatively. Any other appropriate film may be used as the first film 4 and/or the second film 5. In addition, if film-formation materials, reaction gases, and the like differ from those provided above, reactions may proceed differently than as described herein. Further, the present disclosure may apply not only to a CVD apparatus but also to other apparatuses for supplying a gas to a semiconductor substrate, for example.

### (Second Aspect)

Some embodiments according to the first aspect described above include a trap having a cooling mechanism and a heating mechanism that can be implemented to extract and recover a desired gas, and thus an amount of reaction gas consumed can be reduced. In a second aspect, an unreacted gas in a chamber 10 is sent to another chamber, thereby making it possible to reuse a gas (e.g. for another semiconductor device manufacturing process) and to thereby reduce an amount of reaction gas consumed.

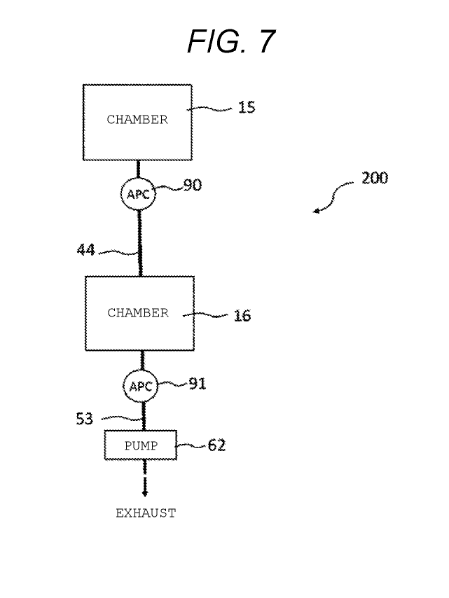

FIG. 7 is a schematic diagram illustrating a configuration of some embodiments of a semiconductor manufacturing apparatus 200 according to the second aspect. The semiconductor manufacturing apparatus 200 includes a first chamber 15, a second chamber 16, a recovery line 44 connecting the first chamber 15 and the second chamber 16, and an exhaust line 53. The recovery line 44 is provided with an auto pressure controller (APC) 90. The exhaust line 53 is connected to the second chamber 16 and is provided with an APC 91. A pump 62 is provided at a terminal of the exhaust line 53.

The first and second chambers 15 and 16 are reaction chambers in which a film-formation process is performed on a surface of a semiconductor substrate 11 using, for example, CVD, and can have, for example, a similar configuration and function as those of the chamber 10 according to the first aspect. The first chamber 15 and the second chambers 16 are each provided with an exhaust tube, and are each connected to the recovery line 44 or the exhaust line 53.

The APCs 90 and 91 are configured to adjust or set the pressure in the first and second chambers 15 and 16, respectively. The APCs are auto pressure controllers that adjust the pressure in the first and second chambers 15 and 16 by changing a flow rate of the reaction gas passing through the recovery line 44 and the exhaust line 53, respectively. That is, the APC makes it possible to control the pressure in a reaction chamber of the semiconductor manufacturing apparatus 200 to keep the reaction chamber at a predetermined pressure (e.g. a pressure value stored in machine-readable instructions stored in a memory accessible to, or part of, the APC). The APC includes a valve or other flow control device. The flow rate of the gas discharged from the reaction chamber of the semiconductor manufacturing apparatus 200 is controlled by the valve (e.g. is set based on a degree of openness of the valve of the APC).

A method of forming a film using the semiconductor manufacturing apparatus 200 according to the second aspect will be described below.

First, a first film formation is performed in the first chamber 15 using CVD, for example, on a semiconductor substrate 11. For example, the first film formation in the first chamber 15 is similar to the formation of the second film 5 described in the first aspect (see FIG. 2A through FIG. 2D). The second film 5 is a tungsten film, for example. In the case of forming the tungsten film, WF₆ is used as a material gas, H₂ is used as a reducing gas, and N₂ or Ar is used as a carrier gas. The reaction represented by the following chemical formula (2) occurs in the first chamber 15.

WF₆(g)+3H₂(g)→W (s)+6HF (g) (2)

For example, it is assumed that a flow of about 10200 standard cubic centimeters per minute (sccm) of supplied reactant gas, which includes about 200 sccm of material gas (WF₆), about 4000 sccm of reducing gas (H₂), and about 6000 sccm of carrier gas (Ar), is supplied to the semiconductor substrate 11 in the first chamber 15. When the above reaction (2) is carried out, at least some of the material gas and at least some of the reducing gas are consumed, and a resultant gas from the reaction includes about 160 sccm of the material gas (WF₆), about 3880 sccm of the reducing gas (H₂), about 6000 sccm of the carrier gas (Ar), and about 240 sccm of by-product (HF) produced by the reaction. That is, during the formation of the tungsten film in the first chamber 15, about one-fifth of the WF₆ gas used as the material gas is consumed. The remaining unreacted gases may be put to another use or reused (e.g. reused in another process of forming the tungsten film). The valves of the APCs 90 and 91 are in an “open” state, and remain in the “open” state in the following description.

Next, for example, the pressure is adjusted by a pump 62, and thus the unreacted gas moves to the second chamber 16 through the recovery line 44. A second film formation is performed in the second chamber 16 using the unreacted gas from the first chamber 15. The second film formation may be performed on the semiconductor substrate 11 subjected to the first film formation, or may be performed on another semiconductor substrate.

Since the amount of the WF₆ gas supplied in the second film formation is smaller than that supplied in the first film formation, and because the amount of the WF₆ gas supplied in the second film formation in the above-described manner may vary depending on reactions that occur in the first film formation, for example, it can be desirable to implement the second film formation in a process in which gas conditions can be generally estimated without a high degree of accuracy, or a process that uses less supplied gas (e.g. in a solid film (flat film) formation process), which may, in some implementations, be performed with a less accurate measure of gas conditions than the process described above for the formation of the second film illustrated in FIG. 2A through FIG. 2D.

When the second film formation is completed in the second chamber 16, the gas in the second chamber 16 is exhausted by adjustment of the pressure with the pump 62.

As described above, according to the semiconductor manufacturing apparatus 200 of the depicted embodiments, the unreacted gas remaining after the first film formation in the first chamber 15 is recovered and is used for the second film formation in the second chamber 16, whereby consumption of the reaction gas (for example, the material gas) can be reduced, and costs can be reduced.

Modified examples of embodiments of the semiconductor manufacturing apparatus 200 according to the second aspect will be described below.

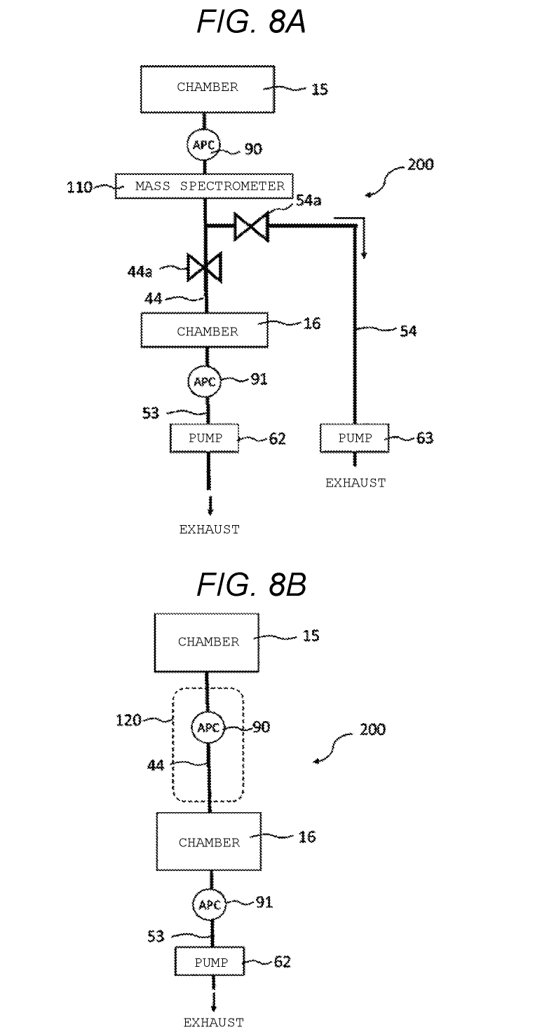

As illustrated in FIG. 8A, in some embodiments, the semiconductor manufacturing apparatus 200 can include a mass spectrometer 110 provided between the APC 90 and the second chamber 16 to analyze gas recovered from the first chamber 15 to determine a composition of the gas. When the mass spectrometer 110 determines that the gas does not have a specified composition, the gas can be exhausted through an exhaust line 54 that branches from the recovery line 44. In the embodiments shown in FIG. 8A, the recovery line 44 is provided with a valve 44a, and the exhaust line is provided with a valve 54a. By opening and closing of the valve, the gas can be recovered or exhausted into the second chamber 16. A controller (not illustrated), which can include a CPU, can control at least one of the valves 54a and 44a based on the determination by the mass spectrometer 110. Furthermore, it is possible to use the exhaust line 54 to exhaust the unreacted gas to the second chamber 16 without recovering it when there is no semiconductor substrate in the second chamber 16, for example.

As illustrated in FIG. 8B, in some embodiments, the semiconductor manufacturing apparatus 200 can include a cooling mechanism 120 provided on the recovery line 44, and a temperature of the recovery line 44 may be set to about 100° C. or lower (e.g. to about 95° C. or lower, to about 90° C. or lower, to about 85° C. or lower, or to about 80° C. or lower). A film formation temperature in the first chamber 15 may be higher than the set temperature of the recovery line 44 (e.g. may be about 400° C., as described above). Therefore, the temperature of a gas exhausted from the first chamber 15 may be high, and components of the gas may react with each other while passing through the recovery line 44 to become an undesired product. Implementing the cooling mechanism 120 may help to prevent this from occurring.

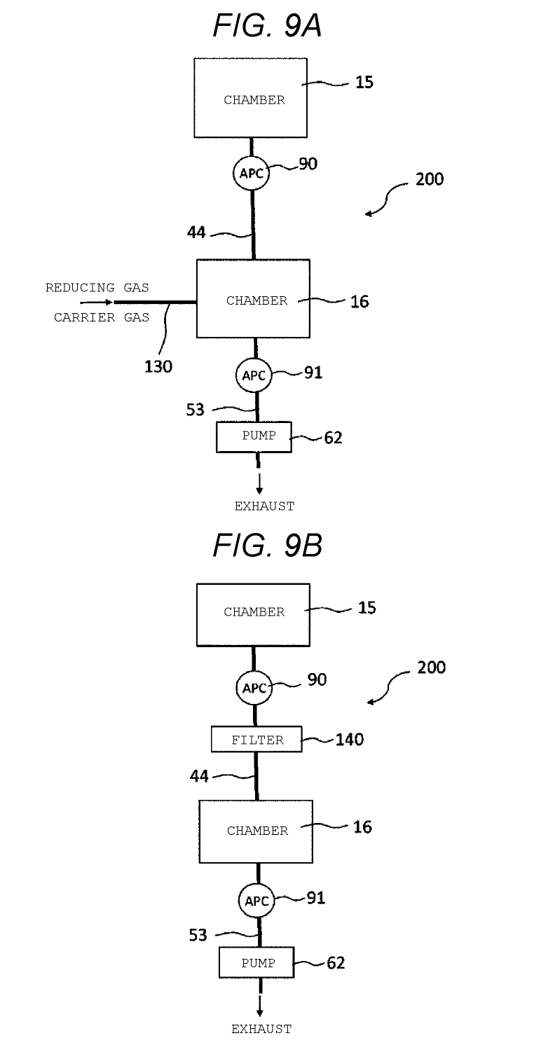

As illustrated in FIG. 9A, in some embodiments, the semiconductor manufacturing apparatus 200 can include a supply line 130 provided to supply a reducing gas or a carrier gas to the second chamber 16. Thereby, for example, even when an amount of the reducing gas or the carrier gas remaining after the first film formation is less than a desired amount, the second film formation can still be performed.

As illustrated in FIG. 9B, in some embodiments, the semiconductor manufacturing apparatus 200 can include a filter 140 provided on the recovery line 44 to remove particles (e.g. undesired particles, such as solid particles). This prevents the particles from entering the second chamber 16 during the film formation that occurs therein.

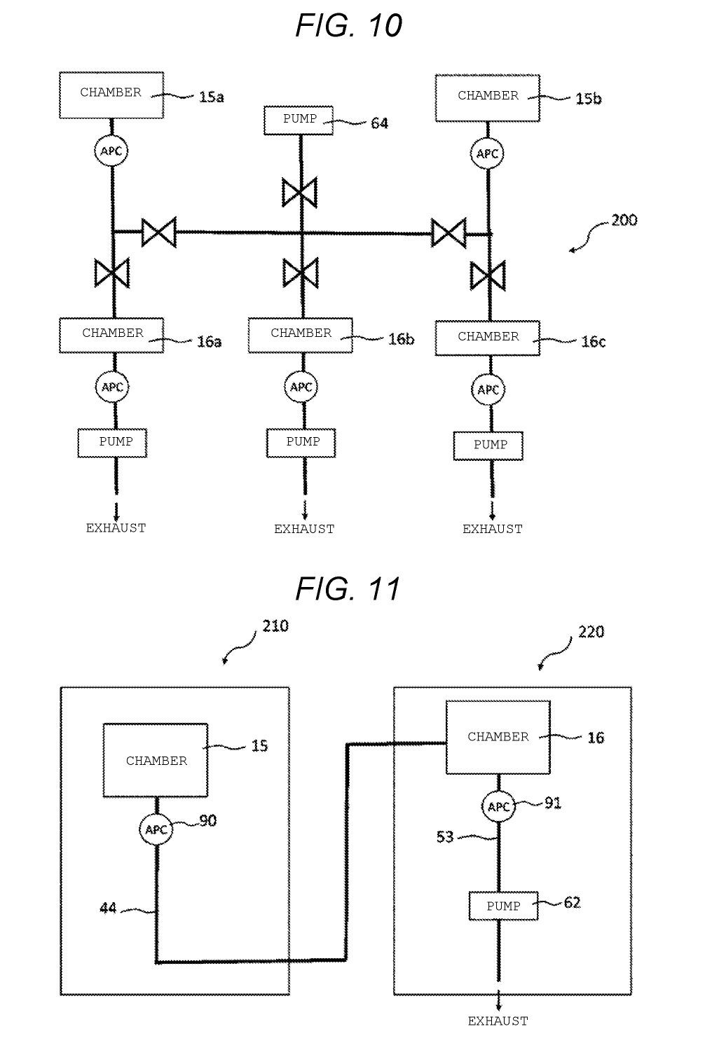

As illustrated in FIG. 10, in some embodiments, the semiconductor manufacturing apparatus 200 can include multiple first chambers including first chambers 15a and 15b and/or multiple second chambers including second chambers 16a, 16b, and 16c. At least some of the first chambers 15a and 15b and the second chambers 16a, 16b, and 16c may share a pump 64. In other embodiments, a different number of chambers may be implemented, including any number of first chambers and any number of second chambers. A recovery line may connect the first chambers 15a and 15b and the second chambers 16a, 16b, and 16c. With this configuration, an unreacted gas exhausted from the first chamber 15a can be recovered into any one of the second chambers 16a, 16b, and 16c. When the multiple first 15a and 15b and second chambers 16a, 16b, and 16c are provided, manufacturing efficiency may be increased.

As illustrated in FIG. 11, in some embodiments according to a third aspect, a semiconductor apparatus can include two semiconductor manufacturing apparatuses 210 and 220 that respectively include a first chamber 15 and a second chamber 16. In other words, the first chamber 15 and the second chamber 16 are provided in separate apparatuses. The first chamber 15 and the second chamber 16 are connected through a recovery line 44.

As described above, according to the second aspect, the unreacted gas used for the first film formation is recovered to perform the second film formation, and thus it is possible to reduce consumption of the desired gas (for example, the material gas) and reduce manufacturing costs. Furthermore, the first film formation and the second film formation are performed using different chambers, and thus the unreacted gas can be readily recovered, thereby more efficiently performing the film formation.

The embodiments described above may be applied to various types of semiconductor devices. For example, the embodiments may be applied to a semiconductor memory device such as a NAND type or a NOR type flash memory, EPROM, DRAM, and SRAM; various logic devices; and/or other semiconductor devices.

As used herein, the term “about” is used to describe and account for small variations. When used in conjunction with an event or circumstance, the term “about” can refer to instances in which the event or circumstance occurs precisely as well as instances in which the event or circumstance occurs to a close approximation. For example, when used in conjunction with a numerical value, the term “about” can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

As used herein, the terms “recovery”, “extraction”, “exhaust”, and “discharge” may, but need not necessarily, refer to complete recovery, extraction, exhaust, or discharge of a predetermined gas; in some implementations, some small about of gas may remain unrecovered, not extracted, not vented, or not discharged (e.g. about 10% of an initial amount of gas or less, about 5% of an initial amount of gas or less, about 3% of an initial amount of gas or less, about 1% of an initial amount of gas or less, about 0.1% of an initial amount of gas or less, or about 0.01% of an initial amount of gas or less), which may still provide for at least some of the advantages of the embodiments described herein.

While certain embodiments have been described, these embodiments have been presented byway of example only, and are not intended to limit the scope of the present disclosure. Indeed, the embodiments described herein may be embodied in a variety of other forms; furthermore, various omissions, substitutions and changes in the form of the embodiments described herein may be made without departing from the spirit of the present disclosure. The accompanying claims and their equivalents are intended to cover such forms or modifications as would fall within the scope and spirit of the present disclosure.

What is claimed is:

1. A semiconductor manufacturing apparatus comprising:
a reaction chamber configured to perform a process on a semiconductor substrate using a gas mixture comprising a first gas;
a first path configured to exhaust resultant gas that comprises the first gas from the reaction chamber;
a first trap provided in the first path and configured to extract at least a portion of the first gas from the resultant gas; and
a second path configured to exhaust the resultant gas from the reaction chamber.

2. The semiconductor manufacturing apparatus according to claim 1, wherein
the first trap includes a control mechanism configured to control a temperature of an interior of the first trap.

3. The semiconductor manufacturing apparatus according to claim 2, further comprising:
a third path configured to exhaust the resultant gas from the reaction chamber, wherein
the third path is provided with a second trap configured to extract at least a portion of the first gas from the resultant gas.

4. The semiconductor manufacturing apparatus according to claim 2, wherein the control mechanism of the first trap is configured to control the temperature of the interior of the first trap to be lower than about 2° C. or higher than about 18° C.

5. The semiconductor manufacturing apparatus according to claim 1, further comprising:
a third path configured to exhaust the resultant gas from the reaction chamber, wherein
the third path is provided with a second trap configured to extract at least a portion of the first gas from the resultant gas.

6. The semiconductor manufacturing apparatus according to claim 1, wherein the first trap is not provided in the second path.

7. The semiconductor manufacturing apparatus according to claim 1, wherein the reaction chamber is configured to perform a film forming process on the semiconductor substrate.

8. The semiconductor manufacturing apparatus according to claim 1, wherein the first gas is a tungsten hexafluoride gas.

9. A semiconductor manufacturing apparatus comprising:
a first reaction chamber configured to perform a first process on a first semiconductor substrate using a gas mixture;
a first path configured to recover resultant gas from the process; and
a second reaction chamber connected to the first path and configured to perform a second process on a second semiconductor substrate using the resultant gas.

10. A method of manufacturing a semiconductor device, comprising:
forming a first film on a semiconductor substrate using a first gas mixture;
discharging the first gas mixture after forming the first film;
forming a second film on the first film using a second gas mixture different from the first gas mixture and comprising a third gas;
extracting the third gas from the second gas mixture after forming the second film to generate a resultant second gas mixture; and
discharging the resultant second gas mixture.

11. The method of manufacturing the semiconductor device according to claim 10, wherein the discharged resultant second gas mixture excludes the third gas.

12. The method of manufacturing the semiconductor device according to claim 10, wherein
the third gas is extracted from the second gas mixture by a process that includes cooling of the second gas mixture.

13. The method of manufacturing the semiconductor device according to claim 12, wherein extracting the third gas from the second gas comprises solidifying the third gas by a cooling process.

14. The method of manufacturing the semiconductor device according to claim 12, wherein the cooling process is performed at a temperature lower than about 2° C.

15. The method of manufacturing the semiconductor device according to claim 12, further comprising heating the third gas after the cooling process.

16. The method of manufacturing the semiconductor device according to claim 15, wherein the heating process is performed at a temperature higher than about 18° C.

17. The method of manufacturing the semiconductor device according to claim 10, wherein the first gas mixture comprises a tungsten hexafluoride gas.
